(19) United States
(12) Patent Application Publication
(10) Pub. No.: US 2024/0332906 A1
(43) Pub. Date: Oct. 3, 2024

(54) EDGE-EMITTING LASER DIODE WITH INCREASED COD THRESHOLD

(71) Applicant: Fraunhofer-Gesellschaft zur Förderung der angewandten Forschung e.V., München (DE)

(72) Inventor: Martin ADAMS, Aachen (DE)

(73) Assignee: Fraunhofer-Gesellschaft zur Förderung der angewandten Forschung e.V., München (DE)

(21) Appl. No.: 18/697,554

(22) PCT Filed: Sep. 27, 2022
(86) PCT No.: PCT/EP2022/076789

§ 371 Date: May 13, 2024

(30) Foreign Application Priority Data
Sep. 30, 2021 (DE) 10 2021 125 392.6

(51) Int. Cl. H01S 5/20; H01S 5/042; H01S 5/10

(52) U.S. Cl. CPC H01S 5/2018; H01S 5/0421; H01S 5/1003

(57) ABSTRACT

The present invention relates to an edge-emitting laser diode which has a semiconductor heterostructure consisting of at least one active layer or layer sequence (4) between two wave-guiding semiconductor layers or layer sequences(3, 5), which extend between a rear (9) and a front facet (10) of the laser diode. Between the rear (9) and the front facet (10), the two wave-guiding semiconductor layers or layer sequences (3, 5) each have one or more modified portions (14), in which vertical leakage currents from the active layer or layer sequence (4) are reduced or suppressed by a design of the two wave-guiding semiconductor layers or layer sequences (3, 5) that is modified in comparison with the remaining portions. The modified portions (14) are arranged in positions in which undesired excessive temperature increases would occur if the laser diode were operated without said reduction or suppression of the vertical leakage currents. The resulting increase in the COD threshold increases the achievable optical output performance and the service life of the laser diode.

### TECHNICAL APPLICATION AREA

The present invention relates to an edge-emitting laser diode which has a semiconductor heterostructure consisting of at least one active layer or layer sequence between two wave-guiding semiconductor layers or layer sequences, which extend between a rear and a front facet of the laser diode, and an electrical contact layer arranged above the semiconductor heterostructure for current injection, on a substrate.

The optical output performance and service life of edge-emitting laser diodes are substantially limited by thermal rollover and catastrophic optical degradation (COD). In the case of thermal rollover, a rise in the average temperature of the semiconductor chip of the laser diode due to the power loss occurring during operation leads initially to a flattening of the performance characteristic and finally to a reversible reduction of the output performance with the injection of increased current strength. In the case of COD on the other hand, a highly localised intense temperature rise, also referred to in the present patent application as excessive temperature increase, results in an irreversible drop in the emitted power in the range of high output performances because of damage to the semiconductor material. This excessive temperature increase often takes place close to the front facet of the laser diode from which the laser beam is emitted.

The service life of laser diodes is limited by gradual degradation, in which a slow decrease in the optical output performance takes place as a function of the operating period, and by the catastrophic optical degradation described previously. The cause of the gradual degradation may be linked to the development of point defects in the semiconductor crystal, which are accelerated by higher temperatures and mechanical stresses, as well as other influences.

### PRIOR ART

Thermal rollover can be prevented by improved cooling of the laser diodes or reduction of the incident heat output. Various measures are known for this purpose, such as a double-sided or active cooling, use of heat sinks with high thermal conductivity, reduction of the serial resistance and the optical absorption by adapting the design of the semiconductor heterostructure, or also a reduction of the thermal resistance through the user of longer semiconductor chips and widening of the injection stripe (broad area emitters). In this way, it is also possible to limit the effects of gradual degradation at the same time, as this is determined mainly by the average temperature in the semiconductor chip.

Regarding catastrophic optical degradation (COD), a number of different approaches are known for increasing the power threshold for the occurrence of COD, with the purpose of preventing a sharp local rise in temperature, particularly on the facets of the semiconductor chip. In one of these approaches, the maximum optical intensity on the front facet is reduced by widening the injection stripe (broad area emitter) and enlarging the waveguide in the vertical direction (large optical cavity). Another approach for increasing the COD threshold consists in coating the facets of the laser diode with suitable layer systems, which saturate the bonds at the fracture edge of the crystal thereby resulting in a reduction of the defect density in the semiconductor in the region of the facets. These defects may form non-radiating recombination centres for the injected charge carriers and lead to the optical absorption of the emitted laser radiation, and consequently cause a sharp temperature increase at the facets.

In a further known technique, the current injected from the p-side of the semiconductor heterostructure is blocked close to the facets (referred to as non-injecting mirror), as is described for example in F. Rinner et al., “Facet temperature reduction by a current blocking layer at the front facets of high-power InGaAs/AlGaAs lasers,” Journal of Applied Physics, vol. 93, no. 3, pp. 1848-1850, 2003. One of the effects of the locally suppressed current flow is that the temperature at the facets is reduced due to the absence of Joule heating. Another effect is the reduction of the charge carrier density at the facets, which is considered to be a critical driver of COD. The local blocking of the injected current may be assured for example by the local application of a dielectric layer before the p-contact of the laser diode is metallised.

A sharp local increase in temperature can also cause absorption of the laser light propagating in the waveguide due to the resulting shift towards higher wavelengths of the optical amplification spectrum in the active zone of the semiconductor heterostructure. The onset of this absorption is widely considered to be the starting point for COD. Enlarging the band gap of the quantum film as the active layer of the laser diode in the vicinity of the facets (referred to as non-absorbing mirror) ensures that this absorption only occurs at higher temperatures, and so raises the COD threshold. The process can be implemented for example by quantum-well intermixing, as is described in S. D. McDougall et al., “Monolithic integration via a universal damage enhanced quantum-well intermixing technique,” IEEE J. Select. Topics Quantum Electron., vol. 4, no. 4, pp. 636-646, 1998, or in C. L. Walker et al., “Improved catastrophic optical damage level from laser with nonabsorbing mirrors,” IEEE Photon. Technol. Lett., vol. 14, no. 10, pp. 1394-1396, 2002, for example.

The object of the present invention consists in suggesting a design for an edge-emitting laser diode, by which the power threshold for the occurrence of catastrophic optical degradation and therewith also the achievable optical output performance and the service life of the laser diode are increased.

### SUMMARY OF THE INVENTION

The object is solved with the edge-emitting laser diode according to Claim 1. Advantageous variants of this laser diode are the object of dependent claims or may be discerned from the following description and the exemplary embodiments.

The suggested edge-emitting laser diode includes a semiconductor heterostructure consisting in known manner of at least one active layer or layer sequence (e.g. multiquantum films) between two wave-guiding semiconductor layers or layer sequences which extend between a rear and a front facet of the laser diode, and an electrical contact layer arranged over the semiconductor heterostructure for current injection on a substrate, in particular a semiconductor substrate. In this arrangement, the laser radiation generated by the laser diode exits through the front facet. The two wave-guiding semiconductor layers or layer sequences are in direct contact with the active layer or layer sequence or border the active layer or layer sequence through one or more transition layers. The cladding layers are typically also positioned adjacently above and below the wave-guiding semiconductor layers or layer sequences. Still more semiconductor or other layers may also be connected. In addition, transition layers may also be constructed between the various layers or layer sequences. The suggested laser diode is characterized in that the two wave-guiding semiconductor layers or layer sequences between the rear and the front facet each have one or more locally delimited modified portions, by which vertical leakage currents from the active layer or layer sequence that arise when the laser diode is operated are reduced or suppressed. The reduction or suppression of the vertical leakage currents is assured by a design of the wave-guiding semiconductor layers or layer sequences in the respective modified portion that is modified in comparison to the one or more portions remaining between the rear and the front facet. The one or more modified portions are arranged in positions in which undesired excessive temperature increases—that is to say sharp local rises in temperature—would occur if the laser diode were operated without said reduction or suppression of the vertical leakage currents, resulting in a COD. In this context, vertical leakage currents are understood to mean leakage currents that propagate out of the active layer or layer sequence substantially vertically to the active layer or layer sequence into neighbouring layers of the semiconductor heterostructure. Locally delimited portions are understood to mean portions that do not extend over all or most of the length of the waveguide between the front and the rear facet, but only over a small part thereof in each case, which is preferably equivalent to <3% of said length in each case.

Vertical leakage currents may occur in addition to the abovementioned onset of absorption in the course of the COD. The absorption due to shift of the amplification spectrum causes an intense local increase in the charge carrier density inside the active layer or layer sequence or zone. If a critical value is exceeded then, these charge carriers diffuse into the surrounding semiconductor layers despite the existing energy barrier and recombine there non-radiantly. The resulting increase in the local heat source causes a further rise in temperature, reinforcing the effect continuously, and finally leading to the destruction of the laser diode when the melting temperature of the semiconductor material is reached. In the context of the present invention, it was found that the power threshold for the occurrence of COD can be raised by a local reduction or suppression of said vertical leakage currents at the one or more critical points through appropriate local modification of the wave-guiding semiconductor layers or layer sequences that directly adjoin the active layer or layer sequence or which border them through one or more transition layers. Simulation calculations show that a positive feedback loop is only started with the initiation of the vertical leakage currents, and then produces progressively stronger heat sources, and thus ultimately leads to the local melting of the semiconductor material and irreversible damage to the laser diode. Accordingly, the local modification of the wave-guiding semiconductor layers or layer sequences for the local reduction or suppression of these vertical leakage currents thus makes it possible to achieve a higher optical output performance and a longer service life of the laser diode.

In this context, the local modification is typically made in a locally delimited portion in the region of the front facet or in a locally delimited portion in the regions of both the front facet and the rear facet, since these regions are identified as frequent starting points for COD in edge-emitting laser diodes. However, an excessive temperature increase can also occur on other longitudinal portions between the front and the rear facet depending on the laser diode type, so then a corresponding local modification of the wave-guiding semiconductor layers or layer sequences is carried out on these portions.

The reduction or suppression of the vertical leakage currents may be achieved through different local modifications of the wave-guiding semiconductor layers or layer sequences, that is to say a modified design of these semiconductor layers or layer sequences compared with the remaining portions. In a variant of the suggested laser diode, for this purpose the band gap of the wave-guiding semiconductor layers or layer sequences is enlarged in the respective modified portion compared to the one or more remaining portions. In this way, the energy barrier between the active layer or layer sequence and the surrounding semiconductor layers is increased and the diffusion of the charge carriers is suppressed. This in turn results in a reduction or suppression of the vertical leakage currents in these areas.

In a further variant of the suggested edge-emitting laser diode, the one or more modified portions of the two wave-guiding semiconductor layers or layer sequences are constructed in such manner that the mobility of the charge carriers is reduced compared with the one or more remaining portions. Due to this reduction of the charge carrier mobility in the wave-guiding semiconductor layers or layer sequences, the diffusion coefficient is reduced locally, and consequently the diffusion current is suppressed. This too leads to a reduction or suppression of the vertical leakage currents and therewith an increase in the COD threshold.

In the case of the suggested edge-emitting laser diode it is preferably only the wave-guiding semiconductor layers or layer sequences, but not the active layer or layer sequence that are locally modified. In other embodiments, a combination of the two variants described above, or of one or both of the abovementioned variants with one or more of the measures for raising the DOC threshold explained in the introduction to the description can also be used in the suggested edge-emitting laser diode. A combination of such kind serves to raise the COD threshold and therewith also increases the service life of the laser diode which is limited by COD.

The present invention may be implemented with all types of edge-emitting laser diodes. But it may be used particularly advantageously for the production of edge-emitting laser diodes that are intended to deliver high optical output performances, for example in the field of laser material processing as direct diode laser systems or as pump modules for fibre and disc lasers. The invention may also be implemented advantageously for laser systems that demand a high level of reliability, for example in transatlantic optical telecommunication or for use in space.

### BRIEF DESCRIPTION OF THE DRAWINGS

In the following text, the suggested edge-emitting laser diode will be explained again, in greater detail, with reference to exemplary embodiments thereof in conjunction with the drawings. In the drawings:

FIG. 1 shows an example of a typical heterostructure of an edge-emitting laser diode according to the prior art in the vertical-longitudinal plane;

FIG. 2 shows an example of the design of the heterostructure of a laser diode according to FIG. 1 using a non-injecting mirror according to the prior art;

FIG. 3 shows an example of the variation of the heterostructure of a laser diode according to FIG. 1 using a non-absorbing mirror according to the prior art;

FIG. 4 shows an exemplary embodiment for the design of the heterostructure for local suppression of vertical leakage currents out of the active layer according to the present invention;

FIG. 5 shows an example of the curve of the band gap along the cross sections A and B indicated in FIG. 4 with local enlargement of the band gap in the layers adjacent to the active layer;

FIG. 6 shows an example of the curve of the charge carriers along the cross sections A and B indicated in FIG. 4 with a local reduction of mobility in the layers adjacent to the active layer; and

FIG. 7 shows an exemplary embodiment for the design of the heterostructure according to the present invention in combination with measures of the prior art.

### WAYS TO IMPLEMENT THE INVENTION

The suggested edge-emitting laser diode has in known manner a semiconductor-heterostructure with at least one active layer between two wave-guiding semiconductor layers on a substrate. FIG. 1 shows a simplified, schematic representation of an example of the typical heterostructure of an edge-emitting laser diode in the vertical-longitudinal plane. The heterostructure in this example has a layer sequence consisting of a n-cladding 2, a n-waveguide 3, the active layer 4, a p-waveguide 5 and a p-cladding 6 on a n-substrate 1. A p-contact 7 for current injection is applied on top of this layer sequence of semiconductor layers. The rear of the n-substrate 1 is furnished with a n-contact 8. The rear facet 9 and the front facet 10 of this laser diode are also indicated in the Figure. The laser beam 11 generated by the laser diode exits through the front facet 10.

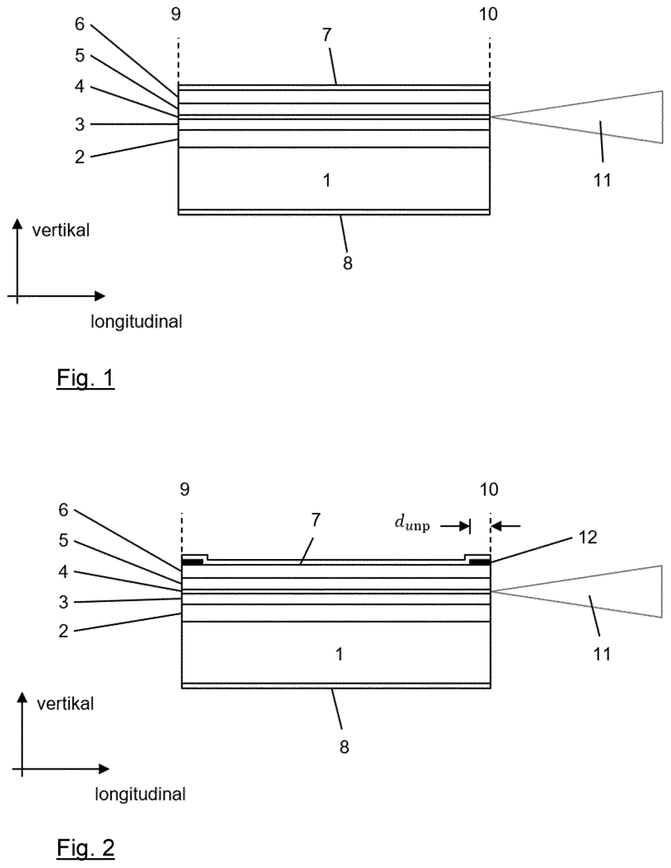

In order to avoid local excessive temperature increases, which often occur at the front facet 10 and the rear facet 9 of an edge-emitting laser diode of this kind, the measures described in the introduction to the description are known. To this end, FIG. 2 shows an example of these measures, the “non-injecting mirror”, for suppressing the current injected at p-contact 7 in an area dᵤₙₚ on the facets 9, 10. A dielectric layer is applied locally in this area as an isolator 12 before the metallisation with the p-contact 7 when the laser diode is manufactured, as is indicated in FIG. 2. This isolator 12 has the effect of locally suppressing the flow of current from the p-contact 7 into the heterostructure, thereby reducing the temperature at the facets 9, 10 due to the absence of Joule heating.

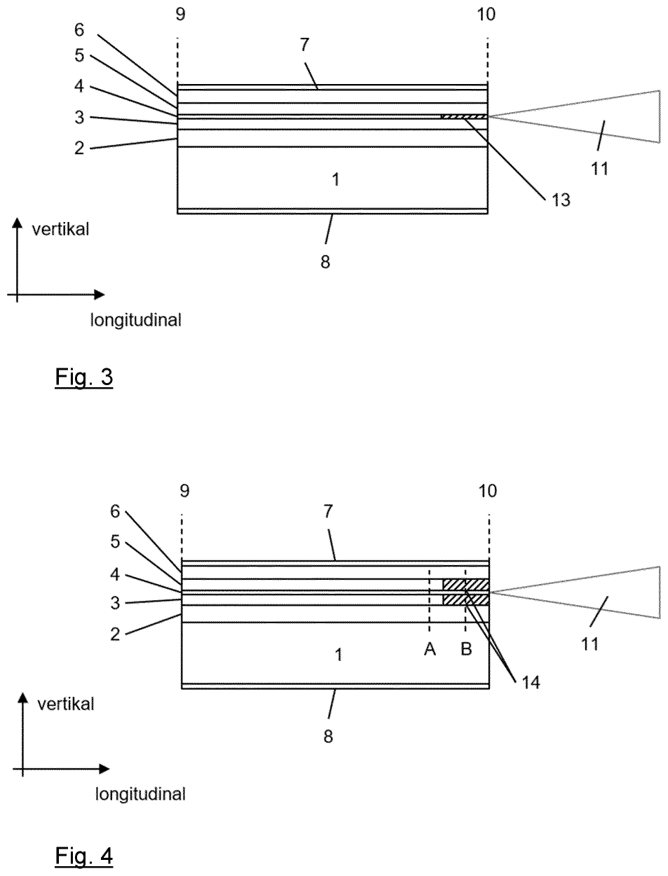

FIG. 3 shows a further example of a known measure for increasing the COD threshold, the “non-absorbing mirror”, as was explained briefly in the introduction to the description. To this end, the active layer 4 in the present example is modified in the area of the front facet 10 in such a way that it has an increased band gap. The corresponding locally modified portion 13 with increased band gap is indicated in FIG. 3. This increase of the band gap ensures that because of a shift of the optical amplification spectrum of the active zone caused by a temperature rise, an absorption of the laser radiation propagating in the waveguide only occurs at higher temperatures, thus raising the COD threshold.

Finally, FIG. 4 shows an exemplary embodiment of the suggested edge-emitting laser diode, which is also represented in simplified, schematic form. In this laser diode, the n-waveguide 3 and the p-waveguide 5 are modified locally in the portions 14 adjacent to the front facet 10 in such manner that in these portions 14 of the semiconductor layers 3, 5 that border the active layer 4 there is an increased band gap and/or reduced mobility of the charge carriers occurs, and consequently the vertical leakage currents from the active layer 4 are reduced or suppressed in this area. In the example of FIG. 4, this local modification is only represented at the front facet 10. This modification may also be made alternatively or additionally at the rear facet 9 or at other longitudinal positions between rear facet 9 and front facet 10 of the heterostructure depending on where the excessive temperature increases occur. The length of these locally delimited modified portions may be in the range from 30 μm to 100 μm, for example.

A local increase of the band gap may be created in the corresponding portions during the manufacture of the laser diode with the following processes, for example. One possibility consists in etching the heterostructure back locally in the portions that are to be modified during manufacture and performing epitaxial regrowth of the waveguide structure with increased band gap in the layers 3, 5 adjoining the active layer 4. Another option consists in implanting suitable ions in said portions in the waveguide layers 3, 5 adjacent to the active layer 4 with subsequent high-temperature treatment to remedy the defects formed, as is described for example in P. G. Piva et al., “Reduction of InGaAs/GaAs laser facet temperatures by band gap shifted extended cavities,” Appl. Phys. Lett., vol. 70, no. 13, pp. 1662-1664, 1997. A third possibility consists in a local vapour deposition of a dielectric layer on each semiconductor layer grown, followed by high-temperature treatment to enable the defects formed on the boundary surface of the dielectric layer to diffuse into the semiconductor layer, as is also described in conjunction with the active layer in the previously cited publication by S. D. McDougall et al. for example. Of course, this is not an exhaustive list. Inward diffusion or implantation of defects is also not the actual process by which the band gap is enlarged. The defects merely facilitate the atomic interdiffusion (intermixing) between different neighbouring semiconductor layers. Consequently, in order to increase the band gap in the wave-guiding semiconductor layers, the defects must only be diffused or implanted into the wave-guiding layers and the cladding layers, not into the active layer, so that intermixing does not take place between the active layer and the waveguide, but between the waveguide and the cladding layer in which the band gap is larger than in the waveguide.

FIG. 5 shows an example of the curve of the band gap in portions 14 modified in this way along the two cross sections A and B marked in FIG. 4. This illustration shows the increase of the band gap exclusively in the correspondingly modified portions of the n-waveguide 3 and the p-waveguide 5, which results in a reduction or suppression of the vertical leakage currents. Thus, for example for a change in the band gap in the range from 120 to 180 meV in the semiconductor layers 3, 5 neighbouring the active layer 4, a clear increase of about 30% in the COD threshold may be achieved, as was determined with simulation calculations. In order to increase the band gap, ions of boron, silicon or zinc for example may be used to this end. This is also true for the reduction of the mobility of the charge carriers by ion implantation described below.

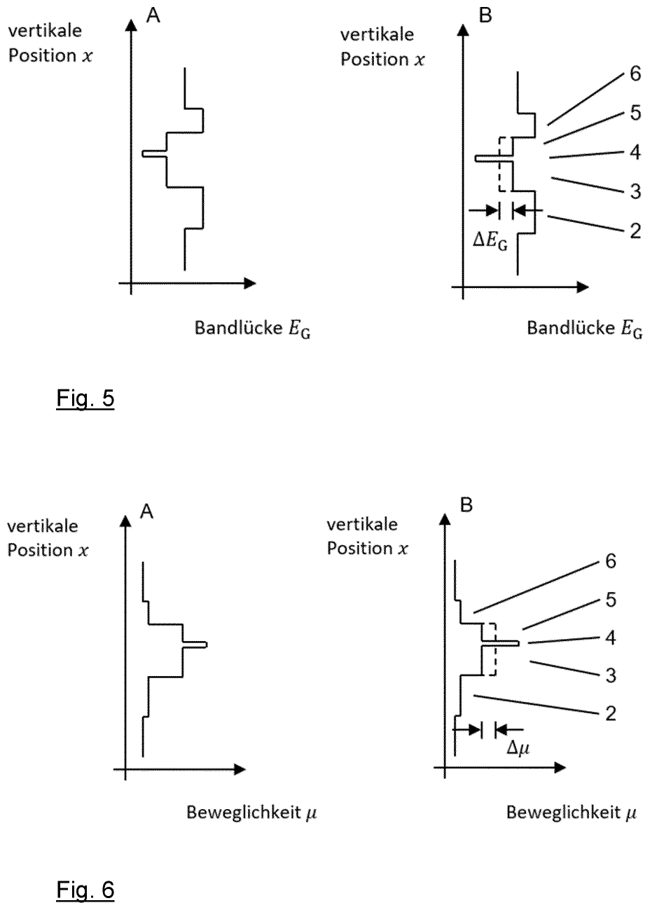

In the case of a reduction of the mobility of the charge carriers in the modified portions 14 represented in FIG. 4, a curve of the mobility of the charge carriers may be produced such as is illustrated in FIG. 6 along the two cross sections A and B marked in FIG. 4. From this representation, it is evident that the mobility in the modified portions 14 of the layers (p-waveguide 5 and n-waveguide 3) adjacent to the active layer has been lowered by a value Δμ. This reduction of mobility may be achieved with various measures during the manufacture of the laser diode. One of these measures consists in the local implantation of suitable ions in the portions of the semiconductor layers 3, 5 to be modified that border the active layer 4. In this context, the dopants must be selected such that they not only create lattice defects—and thus reduce the mobility of the charge carriers—but also that they do not increase current conductivity, as in the case of electrically active dopants. When the ions are implanted, the high-temperature step that usually follows during doping to correct the defects created must be omitted, in order to reduce the mobility of the charge carriers correspondingly. A further possibility consists in an oxidation of said semiconductor layers 3, 5, but not of the active layer, in vicinity of the respective facet. This oxidation then takes place before a coating is applied to the facet from the side into the respective layers. A further possible measure for the local reduction of charge carrier mobility consists in a local modification or disruption of the crystal structure of the corresponding portion with a high-power ultrashort pulse laser. In this process, the wavelength of the laser used must be selected such that the semiconductor layer is sufficiently transparent for the laser radiation. In this case too of course, this list of options is not exhaustive.

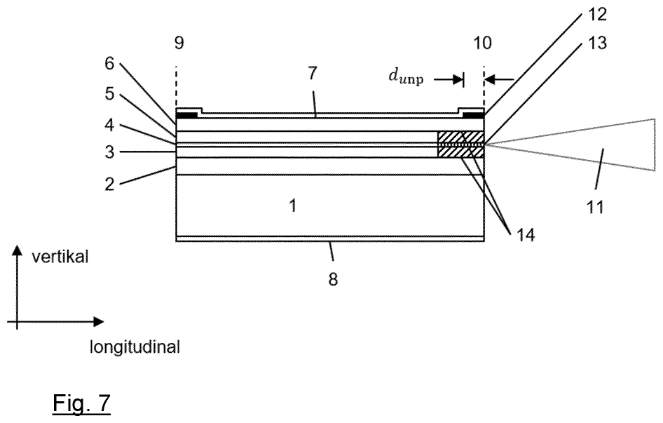

The techniques for increasing the COD threshold already known can be used additionally with the suggested edge-emitting laser diode. FIG. 7 shows a corresponding example, in which the measures suggested according to the invention have been combined with the techniques from FIGS. 2 and 3. Accordingly, besides the locally modified portions 14 in the semiconductor layers 3, 5 adjacent to the active layer 4, the laser diode in this example also has an increased band gap in an area 13 of the active layer 4 in the vicinity of the front facet 10, and isolating areas 12 below the p-contact 7 at the front facet 10 and at the rear facet 9, as is shown in FIG. 7.

### LIST OF REFERENCE NUMERALS

1 n-substrate
2 n-cladding
3 n-waveguide
4 Active layer
5 p-waveguide
6 p-cladding
7 p-contact
8 n-contact
9 Rear facet
10 Front facet
11 Laser beam
12 Isolator
13 Locally modified area of the active layer
14 Locally modified portion of the waveguide

1: An edge-emitting laser diode comprising:
a semiconductor heterostructure including at least one active layer or layer sequence between two wave-guiding semiconductor layers or layer sequences, which extend between a rear and a front facet of the laser diode; and
an electrical contact layer for injecting current arranged over the semiconductor heterostructure on a substrate, wherein
the two wave-guiding semiconductor layers or layer sequences each having one or more locally delimited modified portions between the rear facet and the front facet, in which vertical leakage currents from the active layer or layer sequence during operation of the laser diode are reduced or suppressed by a design of the respective wave-guiding semiconductor layer or layer sequence that is modified in comparison with one or more remaining portions between the rear facet and the front facet, and
the one or more locally delimited modified portions are arranged in positions in which undesired excessive temperature increases would occur if the laser diode were operated without said reduction or suppression of the vertical leakage currents.

2: The edge-emitting laser diode according to claim 1, wherein
a band gap of the one or more locally delimited modified portions is enlarged compared with the one or more remaining portions.

3: The edge-emitting laser diode according to claim 1, wherein
a mobility of the charge carriers in the one or more locally delimited modified portions is reduced compared with the one or more remaining portions.

4: The edge-emitting laser diode according to claim 3, wherein
the two wave-guiding semiconductor layers or layer sequences are oxidised in the one or more locally delimited modified portions.

5: The edge-emitting laser diode according to claim 1 wherein
the two wave-guiding semiconductor layers or layer sequences are doped in the one or more locally delimited modified portions and not doped in the one or more remaining portions, or the one or more locally delimited modified portions have a composition or concentration of dopants that has been modified compared with the one or more remaining portions.

6: The edge-emitting laser diode according to claim 1 wherein
starting from the substrate the semiconductor heterostructure includes, arranged in the following order, at least one n-doped cladding layer or layer sequence, a first one of the two wave-guiding semiconductor layers or layer sequences, the at least one active layer or layer sequence, a second one of the two wave-guiding semiconductor layers or layer sequences, and a p-doped cladding layer or layer sequence.

7: The edge-emitting laser diode according to claim 1 wherein
the one or more locally delimited modified portions are arranged on or in the vicinity of the front facet and/or the rear facet.

8: The edge-emitting laser diode according to claim 2, wherein
a mobility of the charge carriers in the one or more locally delimited modified portions is reduced compared with the one or more remaining portions.

9: The edge-emitting laser diode according to claim 8, wherein
the two wave-guiding semiconductor layers or layer sequences are oxidised in the one or more locally delimited modified portions.
